(19) United States
(12) Patent Application Publication
(10) Pub. No.: US 2015/0303178 A1
(43) Pub. Date: Oct. 22, 2015

(54) CHIP PACKAGE AND METHOD OF MANUFACTURING THE SAME

(71) Applicant: XINTEC INC., Taoyuan City (TW)

(72) Inventors: Chien-Hung LIU, New Taipei City (TW); Ying-Nan WEN, Hsinchu City (TW)

(21) Appl. No.: 14/692,613

(22) Filed: Apr. 21, 2015

(30) Foreign Application Priority Data
Apr. 22, 2014 (TW) 103114537

(51) Int. Cl. H01L 25/16; H01L 21/56; H01L 23/00; H01L 25/00; H01L 23/31; H01L 23/04

(52) U.S. Cl. CPC H01L 25/16; H01L 23/3107; H01L 23/04; H01L 24/06; H01L 25/50; H01L 21/56; H01L 2224/02371; H01L 2924/37001

(57) ABSTRACT

A chip package includes a semiconductor chip, a first chip, a first connection portion, a molding layer, a metal redistribution layer and a packaging layer. The semiconductor chip includes a first conductive pad and a second conductive pad disposed on an upper surface of the semiconductor chip. The first chip is disposed on the upper surface, and the first chip has at least a first chip conductive pad. The first connection portion directly electrically connects the first chip conductive pad and the first conductive pad. The molding layer covers the upper surface, the first chip and the first connection portion, and the molding layer is formed with an opening exposing a second conductive pad. The metal redistribution layer is disposed in the opening, electrically connected to the second conductive pad and extending to the molding layer. The packaging layer covers the metal redistribution layer and the molding layer.

### RELATED APPLICATIONS

This application claims priority to Taiwanese Application Serial Number 103114537, filed Apr. 22, 2014, which is herein incorporated by reference.

### BACKGROUND

1. Field of Invention

The present invention relates to method of manufacturing package. More particularly, the present invention relates to a chip package and method of manufacturing the same.

2. Description of Related Art

Chip package has been widely used in many electronic devices in daily life, especially computers, mobile phones and digital cameras. Those electronic devices require multiple functions, high efficiency and compact in size at the same time. As a result, the packaging density has to increase. Multi-chip stacking structure becomes a heated topic in the chip packaging industry.

A chip package having multi-chip stacking structure refers to two or more chips that exert the same or different functions being put in one single chip package by stacking. The two or more chips exerting the same or different functions being stacked together can increase circuitry density and satisfy the purpose of multi-function (e.g., memory, logic calculation, and specific application integrated circuit). One singe chip package can therefore have higher efficiency and meanwhile execute various functions. Multi-chip stacking structure is then developed to meet the requirement.

However, many multi-chip stacking structures exhibit high complexity. The associated process to produce the multi-chip stacking structure is more complex, the cost goes up, and the yield rate declines. Consequently, a more reliable, more suitable for mass production method of manufacturing chip package is a great concern in the industry.

### SUMMARY

The instant disclosure provides a chip package and method of manufacturing the same. The chip package integrates two or more chip I a stack, such that one single chip package has multiple functions and high efficiency. Between the chips, the electrical connection is achieved first within the chip package and then a metal redistribution layer serves as an external connection for the stack of two chips. In one package there will be two chips so as to exert more functionalities and higher efficiency, and at the same time the pattern design of the metal redistribution layer can be simplified. In other words, the metal redistribution layer does not need to electrically connect the semiconductor chip and the first chip directly. Accordingly, there is more flexibility in the pattern design of the metal redistribution layer, and the production cost can be greatly reduced.

The invention provides a chip package including a semiconductor chip, a first chip, a first connection portion, a molding layer, a metal redistribution layer and a packaging layer. The semiconductor chip includes at least a first conductive pad and at least a second conductive pad disposed on an upper surface of the semiconductor chip. The first chip is disposed on the upper surface, and the first chip has at least a first chip conductive pad. The first connection portion directly electrically connects the first chip conductive pad and the first conductive pad. The molding layer covers the upper surface, the first chip and the first connection portion, and the molding layer is formed with an opening exposing a second conductive pad. The metal redistribution layer is disposed in the opening, electrically connected to the second conductive pad and extending to the molding layer. The packaging layer covers the metal redistribution layer and the molding layer.

In an embodiment of the instant disclosure, the chip package further includes a protection glass and a barrier dam. The protection glass is disposed between the semiconductor and the first chip. The barrier dam has a height and is sandwiched between the protection glass and the semiconductor.

In an embodiment of the instant disclosure, the chip package further includes a second chip and a second connection portion. The second chip is sandwiched between the semiconductor chip and the first chip, and the second chip has at least a second chip conductive pad. The second connection portion electrically connects the second conductive pad and the first conductive pad.

In an embodiment of the instant disclosure, an area of the second chip is larger than an area of the first chip.

In an embodiment of the instant disclosure, the second chip is a switch or an oscillator of an integrated passive device, a radio frequency circuit, an analogue device, a digital device, a mixed signal device or a micro-electro mechanical system.

In an embodiment of the instant disclosure, the second connection portion and the first connection portion respectively connect to different first conductive pads.

In an embodiment of the instant disclosure, the chip package further includes a second chip and a second connection portion. The second chip is disposed on the upper surface and adjacent to the first chip, and the second chip has at least a second chip conductive pad. The second connection portion electrically connecting the second chip conductive pad and the first conductive pad.

In an embodiment of the instant disclosure, the second chip is a switch or an oscillator of an integrated passive device, a radio frequency circuit, an analogue device, a digital device, a mixed signal device or a micro-electro mechanical system.

In an embodiment of the instant disclosure, the second connection portion and the first connection portion respectively connect to different first conductive pads.

In an embodiment of the instant disclosure, the chip package further includes a solder ball disposed on the packaging layer. The packaging layer is formed with an opening exposing a portion of the metal redistribution layer. The solder ball is electrically connected to the metal redistribution layer through the opening of the packaging layer.

In an embodiment of the instant disclosure, the first chip is a switch or an oscillator of an integrated passive device, a radio frequency circuit, an analogue device, a digital device, a mixed signal device or a micro-electro mechanical system.

In an embodiment of the instant disclosure, an area of the semiconductor chip is larger than an area of the first chip.

In an embodiment of the instant disclosure, the chip package further includes an adhesive layer sandwiched between the upper surface of the semiconductor chip and the first chip.

In an embodiment of the instant disclosure, the adhesive layer includes a silver glue.

The instant disclosure further provides a method of manufacturing chip package including providing a semiconductor wafer having a plurality of semiconductor chips arranged abreast. The semiconductor chip has at least a first conductive pad and at least a second conductive pad disposed on an upper surface of the semiconductor chip. Next, a plurality of first chips corresponding to the semiconductor chips is formed. The first chips are disposed on the upper surface, and each of the first chip has at least a conductive pad. Then, a plurality of first connection portions is formed and respectively electrically connected to each of the conductive pad of the first chips and each of the first conductive pad. Subsequently, a molding layer is formed, covering the upper surface, the first chip and the first connection portion. The molding layer is formed with an opening exposing the second conductive pad. Afterwards, a metal redistribution layer is formed in the opening and electrically connected to the second conductive pad. The metal redistribution layer extends to the molding layer. Finally, a packaging layer is formed, covering the redistribution layer and the molding layer.

In an embodiment of the instant disclosure, in the step of forming the first chips corresponding to the semiconductor chips further includes forming a plurality of supporting elements corresponding to each of the semiconductor chips and disposed on the semiconductor chip. Further, a plurality of protection glass is formed on each of the supporting elements.

In an embodiment of the instant disclosure, in the step of forming the first chips corresponding to the semiconductor chips further includes forming a plurality of second chips respectively corresponding to the semiconductor chips. The second chips respectively correspond to the semiconductor chips, are sandwiched between the semiconductor chip and the first chip and have at least a conductive pad. Further, a plurality of second connection portions is formed and respectively electrically connected to each of the conductive pads of the second chip and each of the first conductive pads.

In an embodiment of the instant disclosure, an area of the first chip is larger than an area of the second chip.

In an embodiment of the instant disclosure, the second chip is a switch or an oscillator of an integrated passive device, a radio frequency circuit, an analogue device, a digital device, a mixed signal device or a micro-electro mechanical system.

In an embodiment of the instant disclosure, the second connection portion and the first connection portion respectively connect to different first conductive pads.

In an embodiment of the instant disclosure, in the step of forming the first chips corresponding to the semiconductor chips further includes forming a plurality of second chips respectively corresponding to the semiconductor chips. The second chips are disposed on the upper surface of the semiconductor chip and adjacent to the first chip and have at least a conductive pad. Further, a plurality of protection glass is formed on each of the supporting elements.

In an embodiment of the instant disclosure, the second chip is a switch or an oscillator of an integrated passive device, a radio frequency circuit, an analogue device, a digital device, a mixed signal device or a micro-electro mechanical system.

In an embodiment of the instant disclosure, the second connection portion and the first connection portion respectively connect to different first conductive pads.

In an embodiment of the instant disclosure, the method further includes forming a solder ball disposed on the packaging layer. The packaging layer is formed with an opening exposing a portion of the metal redistribution layer, and the solder ball is electrically connected to the metal redistribution layer through the opening of the packaging layer.

In an embodiment of the instant disclosure, the first chip is a switch or an oscillator of an integrated passive device, a radio frequency circuit, an analogue device, a digital device, a mixed signal device or a micro-electro mechanical system.

In an embodiment of the instant disclosure, an area of the semiconductor chip is larger than an area of the first chip.

In an embodiment of the instant disclosure, the method further includes forming an adhesive layer sandwiched between the upper layer of the semiconductor chip and the first chip.

In an embodiment of the instant disclosure, the adhesive layer includes a silver glue.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a partially cross-sectional view of a chip package in accordance with an embodiment of the instant disclosure;

FIG. 2 is a partially cross-sectional view of a chip package in accordance with an embodiment of the instant disclosure;

FIG. 3 is a partially cross-sectional view of a chip package in accordance with an embodiment of the instant disclosure;

FIG. 4 is a plan view showing a process in accordance with an embodiment of the instant disclosure;

FIGS. 5-7 are partially cross-sectional views showing different stages in a process in accordance with an embodiment of the instant disclosure;

FIGS. 8-10 are partially cross-sectional views showing different stages in a process in accordance with an embodiment of the instant disclosure; and

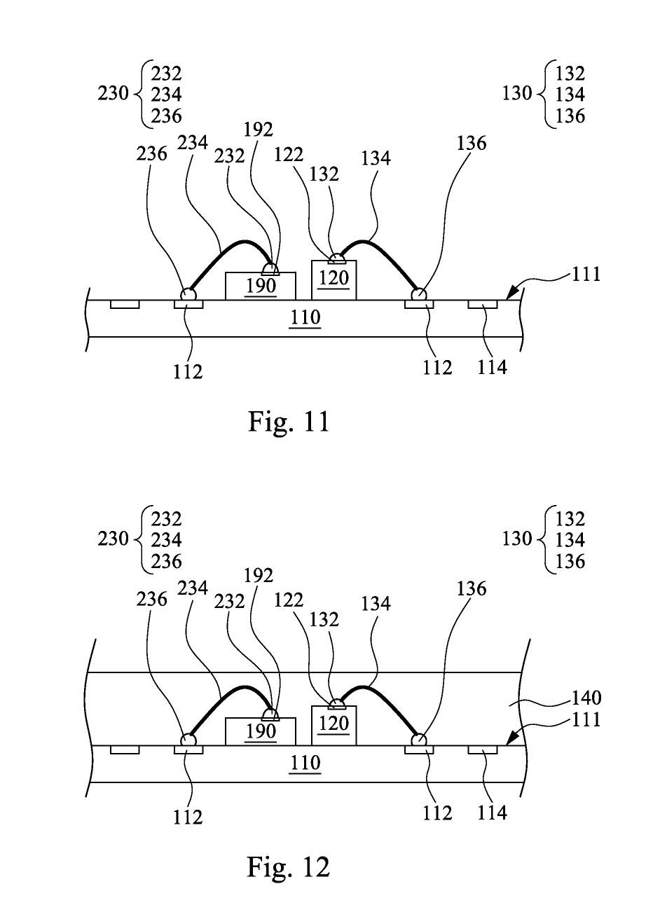

FIGS. 11-13 partially cross-sectional views showing different stages in a process in accordance with an embodiment of the instant disclosure.

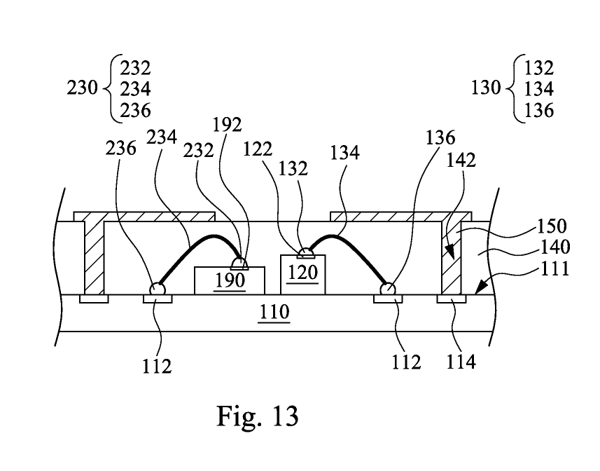

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

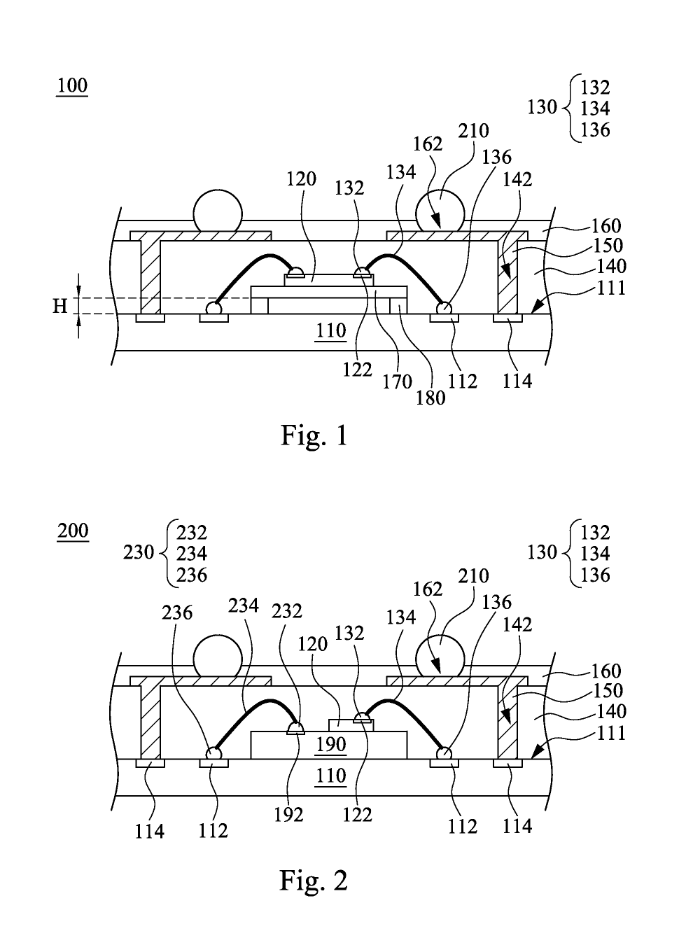

FIG. 1 is a partially cross-sectional view of a chip package 100 in accordance with an embodiment of the instant disclosure. Please refer to FIG. 1. The chip package 100 includes a semiconductor chip 110, a first chip 120, a first connection portion 130, a molding layer 140, a redistribution layer 150, which is a metal redistribution layer in some embodiments, and a packaging layer 160. The semiconductor chip 110 has at least a first conductive pad 112 and at least a second conductive pad 114 disposed on the upper surface 111 of the semiconductor chip 110. The semiconductor chip 110 may be wafer-level semiconductor chip 110 formed on silicon, germanium or other group III-V element semiconductor wafer substrate. The semiconductor chip 110 may have, for example, electronic components (not shown) disposed in the semiconductor chip 110. The electronic component and each of the first conductive pads 112 disposed on the upper surface 111 of the semiconductor chip 110 are electrically connected. Electrical connection can be established by, for example, an interconnect structure (not shown) in the semiconductor chip 110 and connected to electronic components. As a result, the first conductive pad 112 and the second conductive pad 114 can act as signal input/output end of the electronic components in the semiconductor chip 110. Materials of the first and second conductive pads 112, 114 may be, for example, aluminum, copper, nickel or any other suitable conductive materials. In the instant disclosure, the electronic component may be active element, passive elements, electronic components of digital circuit, analogue circuit or integrated circuit, micro electro mechanical systems (MEMS), micro fluidic systems, physical sensor using heat, light or pressure variant for detecting, radio frequency circuits, accelerators, gyroscopes, micro actuators, surface sound wave circuit, pressure sensors or the like.

Still referring to FIG. 1, the first chip 120 is disposed on the upper surface 111. The first chip 120 has at least a first chip conductive pad 122. The similarity between the first chip and the semiconductor chip 110 is elaborated hereinafter. The first chip 120 also has electronic components (not shown) in the first chip 120. The electronic component is electrically connected to the first chip conductive pad 122 disposed on the upper surface 11 of the first chip 120. Electrical connection can be established by interconnect structure (not shown) in the first chip 120 and connected to the electronic component. Therefore, the first chip conductive pad 122 can be the signal input/output end of the electronic component in the first chip 120. Materials of the first chip conductive pad 122 may be aluminum, copper, nickel or any other suitable conductive materials. The difference between the first chip and the semiconductor chip 110 arises from their size. The first chip 120 can be any chip having smaller die size. In some embodiments of the instant disclosure, the semiconductor chip 110 has an area larger that an area of the first chip 120. More specifically, referring to FIG. 1 where the piling structure of the semiconductor chip 110 and the first chip 120 is shown, in the wafer level packaging process of the semiconductor chip 110, the smaller first chip 120 is stacked on the larger semiconductor chip 110, and the electrical connection is then established, such that one single package has more than two chips. A single package integrating two or more chips (semiconductor chip 110 and the first chip 120) can have multiple functions and high efficiency. The first chip 120 can have different functionality and pair up with the semiconductor chip 110 according to the requirement. In some embodiments of the instant disclosure, the first chip 120 is a switch or an oscillator of an integrated passive device, a radio frequency circuit chip, an analogue circuit chip, a digital circuit chip, a mixed signal circuit chip or micro-electro mechanical systems.

Still referring to FIG. 1, the first connection portion 130 directly and electrically connects the first chip conductive pad 122 and the first conductive pad 112. As previously described, the first chip 120 is stacked on the semiconductor chip 110, and then the electrical path between the first chip 120 and the semiconductor chip 110 is achieved by the first connection portion 130. In other words, two ends of the first connection portion 130 respectively connect to the first chip conductive pad 122 of the first chip 120 and the first conductive pad 112 of the semiconductor chip 110. As shown in FIG. 1, the first connection portion 130 may constitute solder ball portions 132, 136 and a solder wire portion 134. The solder ball portion 132 is soldered to the first chip conductive pad 122 of the first chip 120, while the solder ball portion 136 is soldered to the first conductive pad 112 of the semiconductor chip 110. The solder wire portion 134 connects the solder ball portions 132 and 136. As a result, a direct electrical connection is established between the first chip 120 and the semiconductor chip 110. However, the first connection portion 130 is not limited thereto. The first connection portion 130 may be a metal clip or a conductive ribbon whose two ends directly yet respectively contact with the first chip conductive pad 122 and the first conductive pad 112. The first connection portion 130 may be any other suitable couple means that forms direct electrical connection between the first chip conductive pad 122 and the first conductive pad 112. Still referring to FIG. 1, the molding layer 140 covers the upper surface 111, the first chip 120 and the first connection portion 130. The molding layer 140 is formed with an opening 142 exposing the second conductive pad 114. As shown in FIG. 1, the semiconductor chip 110, first chip 120 and first connection portion 130 are packaged as one entity by the molding layer 140. The molding layer 140 may be, for example, formed by molding process which employs molding materials to cover the upper surface 111, the first chip 120 and the first connection portion 130. Materials of the molding layer 140 include epoxy molding compound (EMC) or any other suitable molding materials.

Please refer to FIG. 1. The metal redistribution layer 150 is disposed in the opening 142 and electrically connected to the second conductive pad 114. The metal redistribution layer 150 extends up to the molding layer 140. The metal redistribution layer 150 serves as route for independent signals, controlling the signal input/output of the second conductive pad 114 of the semiconductor chip 110. Materials of the metal redistribution layer 150 include aluminum, copper or any other suitable conductive materials. The metal redistribution layer 150 may be formed by firstly sputtering or evaporation to fill the opening 142 of the molding layer 140 and covers the molding layer 140 to form a conductive film. Then, the conductive film undergoes lithography to form the metal redistribution layer 150 having a predetermined redistribution pattern. As shown in FIG. 1, the packaging layer 160 covers the metal redistribution layer 150 and the molding layer 140. The packaging layer 160 can also envelops the metal redistribution layer 150 so as to block moisture or any other contaminate having direct contact with the metal redistribution layer 150. The metal redistribution layer 150 is therefore protected from breakage caused by corrosion. Materials of the packaging layer 160 may be solder mask or any other suitable packaging materials. The packaging layer 160 conforms to the metal redistribution layer 150 and the molding layer 140 by spin-on coating. In some embodiments of the instant disclosure, the chip package 100 further includes solder balls 210 disposed on the packaging layer 160. As shown in FIG. 1, the packaging layer 160 is formed with openings 162 exposing a portion of the metal redistribution layer 150. The solder ball 210 is electrically connected to the metal redistribution layer 150 through the opening 162 of the packaging layer 160. Materials of the solder balls 210 may be, for example, tin or other alloys suitable for soldering purpose. The solder ball 210 acts as a connection bridge when the chip package 100 externally connects to a printed circuit board (PCB) or other interposer. Input/output signals from the printed circuit board or other interposer can be passed on to the solder ball 210, metal redistribution layer 150 and the second conductive pad 114 of the semiconductor chip 110, and the external devices control the signal input/output of the electronic components within.

As shown in FIG. 1, in some embodiments of the instant disclosure, the chip package 100 further includes a protection substrate 170, which is a protection glass in some embodiments of the instant disclosure, and a spacer 180, which is a barrier dam in some embodiments of the instant disclosure. The protection glass 170 is disposed between the semiconductor chip 110 and the first chip 120. The barrier dam 180 has a height H and is sandwiched between the protection glass 170 and the semiconductor chip 110. In other words, the barrier dam 180 defines a compartment on the upper surface 111 of the semiconductor chip 110. The compartment may serve for different purposes such as accommodating micro lens module or other components that requires independent space. The compartment is then sealed by the protection glass 170. The first chip 120 is disposed on the protection glass 170. In some embodiments of the instant disclosure, the chip package 100 integrates the semiconductor chip 110 and the first chip 120 to fulfill multiple functions and allows more combinations like micro lens module or other components that requires independent space. The application of the chip package is more flexible and broad.

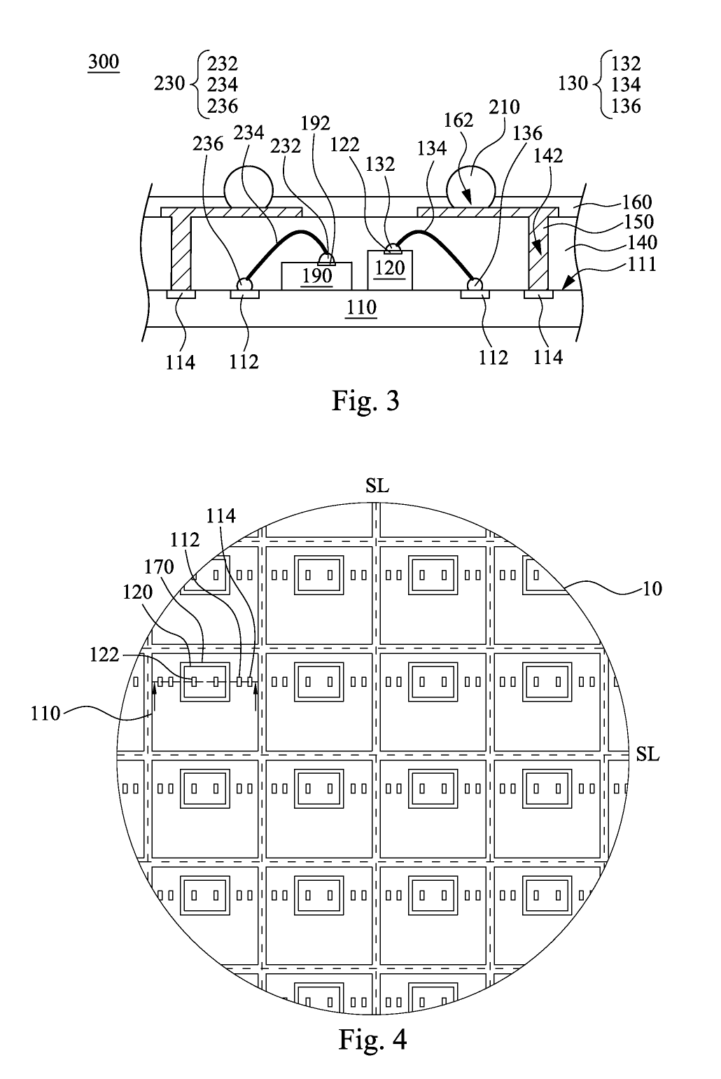

FIG. 2 is a partially cross-sectional view of a chip package 200 in accordance with an embodiment of the instant disclosure. Please refer to FIG. 2. The chip package 200 includes a semiconductor chip 110, a first chip 120, a first connection portion 130, a molding layer 140, a metal redistribution layer 150 and a packaging layer 160. These elements are identical to the ones described in the chip package 100 and hereinafter not repeated to avoid redundancy. The difference between the chip package 200 and the chip package 100 arises from a second chip 190 and a second connection portion 230. The chip package 200 further includes the second chip 190 and the second connection portion 230. The second chip 190 is sandwiched between the semiconductor chip 110 and the first chip 120. The second chip 190 has at least one second chip conductive pad 192, and the second connection portion 230 electrically connects the second chip conductive pad 192 and the first conductive pad 112. The second chip 190 and the semiconductor chip 110 are similar in that the second chip 190 has electronic components (not shown) disposed in the second chip 190. The electronic component is electrically connected to the second chip conductive pad 192 disposed on the upper surface of the second chip 190. The electrical connection may be achieved by an interconnect structure (not shown) in the second chip 190. Consequently, the second chip conductive pad 192 can serve as a signal input/output regulation end of the electronic components in the second chip 190. Materials of the second conductive pad 192 may be aluminum, copper, nickel or any other suitable conductive materials. The difference between the second chip 190 and the semiconductor chip 110 arises from the size. The second chip 190 can be any type of chip having smaller die size. The size of the second chip 190 in relation to the first chip 120 may vary according to practical requirement. As shown in FIG. 2, in some embodiments of the instant disclosure, an area of the second chip 190 is larger than that of the first chip 120. More specifically, as shown in FIG. 2, in the stacking structure of the semiconductor chip 110, first chip 110 and the second chip 190, the second chip 190 that has smaller size and the first chip 120 are stacked on the larger semiconductor chip 110 in succession in the wafer level manufacture of the semiconductor chip 110. Then the electrical connection between them is established. In this way, a single chip package has three chips including semiconductor chip 110, first chip 120 and the second chip 190. The chip package exhibits multiple functions and high efficiency. In addition, according to practical requirement, the second chip 190 may have different functions from the semiconductor chip 110 and the first chip 120, and the combination may vary as long as it suits the desired purpose. In some embodiments of the instant disclosure, the second chip 190 is a switch or an oscillator of an integrated passive device, a radio frequency circuit, an analogue device, a digital device, a mixed signal device or a micro-electro mechanical system. Electrical connection integration of the semiconductor chip 110, first chip 120 and second chip 190 may be serial or parallel or any other suitable connection means. In some embodiments of the instant disclosure, the second connection portion 230 and the first connection portion 130 respectively connect to different first conductive pads 112. As shown in FIG. 2, the second connection portion 230 may constitute solder ball portions 232, 236 and solder wire portion 234. The solder ball portion 232 is soldered to the second chip conductive pad 192 of the second chip 190, while the solder ball portion 236 is soldered to the first conductive pad 112 of the semiconductor chip 110. The solder wire portion 234 connects the solder ball portions 232, 236. The second chip 190 and the semiconductor chip 110 are directly and electrically connected. However, the instant disclosure is not limited thereto. The second connection portion 230 may be metal clip or conductive ribbon whose two ends directly yet respectively contact the second chip conductive pad 192 and the first conductive pad 112.

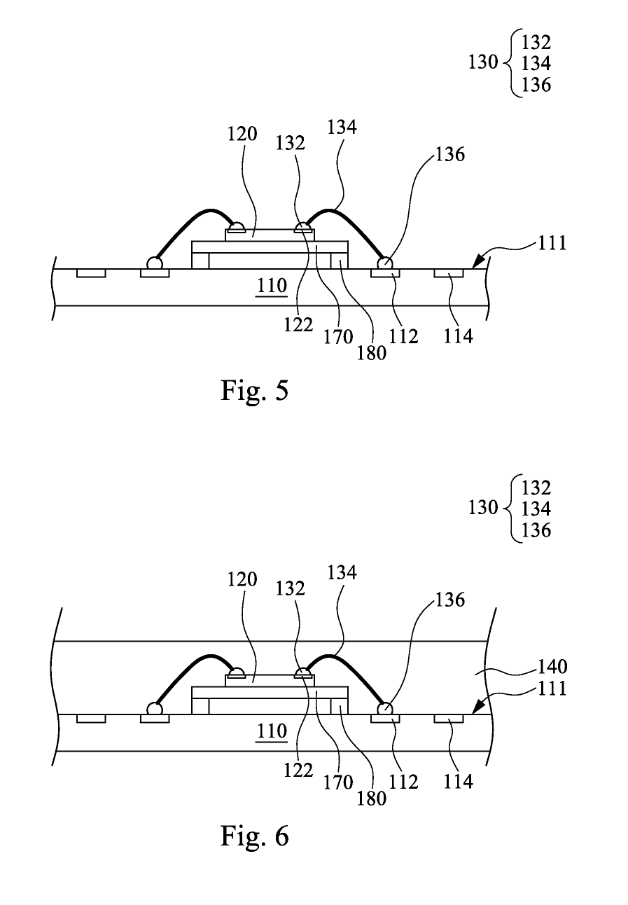

FIG. 3 is a partially cross-sectional view of a chip package 300 in accordance with an embodiment of the instant disclosure. Please refer to FIG. 3. The chip package 300 includes a semiconductor chip 110, a first chip 120, a first connection portion 130, a molding layer 140, a metal redistribution layer 150 and a packaging layer 160. These elements are identical to the ones described in the chip package 100 and hereinafter not repeated to avoid redundancy. The difference between the chip package 300 and the chip package 100 arises from a second chip 190 and a second connection portion 230. The chip package 300 further includes the second chip 190 and the second connection portion 230. The second chip 190 is disposed on the upper surface 111 and adjacent to the first chip 120. The second chip 190 has at least one second chip conductive pad 192, and the second connection portion 230 electrically connects the second chip conductive pad 192 and the first conductive pad 112. The second chip 190 also has electronic components (not shown) disposed in the second chip 190. The electronic component is electrically connected to the second chip conductive pad 192 disposed on the upper surface of the second chip 190. The electrical connection may be achieved by an interconnect structure (not shown) in the second chip 190. Consequently, the second chip conductive pad 192 can serve as a signal input/output regulation end of the electronic components in the second chip 190. Materials of the second conductive pad 192 may be aluminum, copper, nickel or any other suitable conductive materials. The difference between the second chip 190 and the semiconductor chip 110 arises from the size. The second chip 190 can be any type of chip having smaller die size. The size of the second chip 190 in relation to the first chip 120 may vary according to practical requirement. More specifically, as shown in FIG. 3, in the stacking structure of the semiconductor chip 110, first chip 110 and the second chip 190, the second chip 190 that has smaller size and the first chip 120 are stacked on the larger semiconductor chip 110 separately in the wafer level manufacture of the semiconductor chip 110. Then the electrical connection between them is established. In this way, a single chip package has three chips including semiconductor chip 110, first chip 120 and the second chip 190. The chip package exhibits multiple functions and high efficiency. In addition, according to practical requirement, the second chip 190 may have different functions from the semiconductor chip 110 and the first chip 120, and the combination may vary as long as it suits the desired purpose. In some embodiments of the instant disclosure, the second chip 190 is a switch or an oscillator of an integrated passive device, a radio frequency circuit, an analogue device, a digital device, a mixed signal device or a micro-electro mechanical system.

In short, please refer to FIGS. 1 to 3. In some embodiments of the instant disclosure, at least two chips are present namely the semiconductor chip 110 and the first chip 120 stacked to form a chip package. In the chip package, two chips are electrically connected by the first connection portion 130, and then the metal redistribution layer 150 serves to electrically connect the two stacked chips to external components. Two chips are integrated in one package such that one package can have multiple functions and higher efficiency. At the same time, the pattern design of the metal redistribution layer 150 can be more simplified. In other words, the metal redistribution layer 150 does not need to simultaneously, directly and electrically connect to the semiconductor chip 110 and the first chip 120. The metal redistribution layer can be electrically connected to the semiconductor chip 110 alone. The signal input/output of the first chip 120 is controlled by the first connection portion 130 along with the semiconductor chip 110. Accordingly, the pattern design of the simplified metal redistribution layer 150 is more flexible. For example, a broader line on the predetermined area can be arranged, such that breakage is less likely to occur. The method of manufacturing the chip package is elaborated hereinafter.

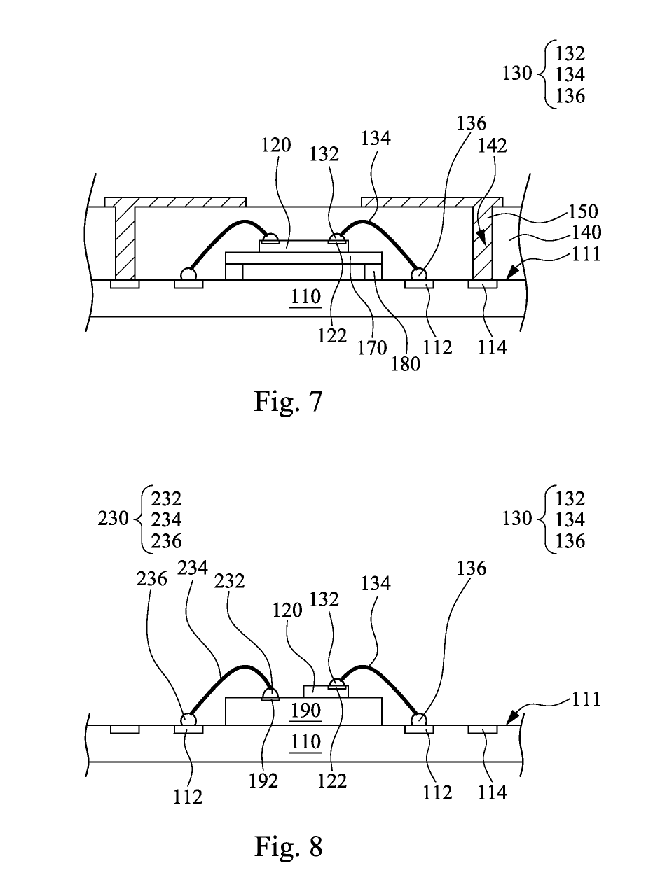

FIG. 4 is a plan view showing a process in accordance with an embodiment of the instant disclosure. Please refer to FIG. 4. A semiconductor wafer 10 is provided. The semiconductor wafer 10 has a plurality of semiconductor chip 110 arranged abreast. Each of the semiconductor chips 110 has at least a first conductive pad 112 and at least a second conductive pad 114 disposed on an upper surface 111 of the semiconductor chip 110. Next, a plurality of first chips 120 is formed on the corresponding semiconductor chip 110. Each of the first chips 120 is disposed on the upper surface 111. Each of the first chips 120 has at least a first chip conductive pad 122. As shown in FIG. 4, the semiconductor wafer 10 has the plurality of semiconductor chips. Each semiconductor chip 110 is arranged along a predetermined scribe line SL of the semiconductor chip 110 that will be cut subsequently. Each first chip 120 is formed on each semiconductor chip 110, and an initial stage of the stacked chip is complete. The semiconductor chip 110 in the method of manufacturing the chip package is a wafer level chip. In other words, each semiconductor chip 110 can be seen as a portion of the semiconductor wafer 10 before slicing. Therefore, before slicing, the process is carried out in a wafer level. However, each first chip 120 is die level chip corresponding to the semiconductor chip 110 on the semiconductor wafer 10. The area ratio of the first chip 120 and the semiconductor chip 110 may vary according to practical requirement. In some embodiments of the instant disclosure, the area of the semiconductor chip 110 is larger than the area of the first chip 120. The attachment means between the first chip 120 and the semiconductor chip 110 may be, for example, forming an adhesive layer sandwiched between the upper surface 111 of the semiconductor chip 110 and the first chip 120. In some embodiments of the instant disclosure, the adhesive layer includes silver glue.

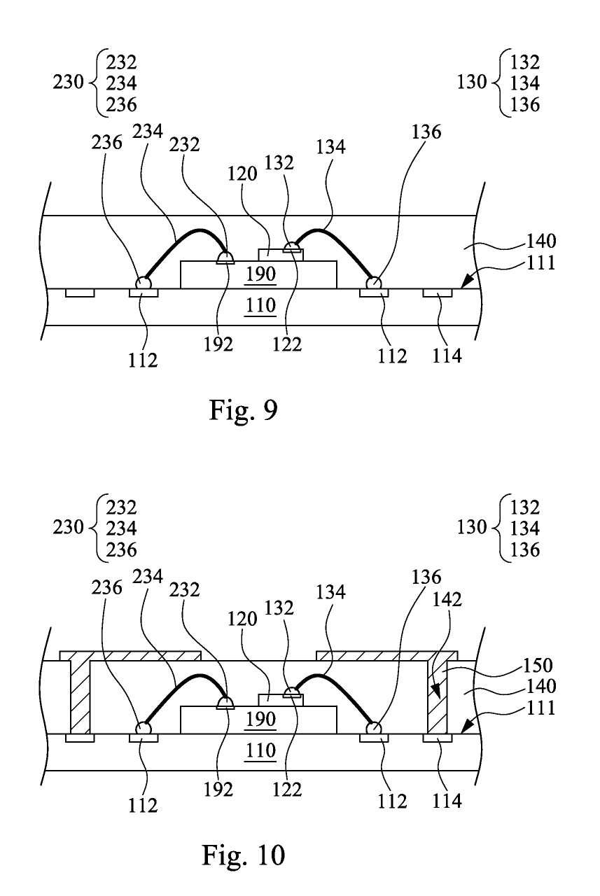

FIGS. 5-7 are partially cross-sectional views showing different stages in a process in accordance with an embodiment of the instant disclosure. Please refer to FIG. 5 in conjunction with FIG. 4. In some embodiments of the instant disclosure, before each first chip 120 corresponding to each semiconductor chip 110 is formed, the process further includes formation of a plurality of barrier dams 180 corresponding to each semiconductor chip 110 and disposed on each semiconductor chip 110. Next, a plurality of protection glass 170 is formed on the barrier dams 180. As shown in FIG. 5, in some embodiments of the instant disclosure, the process further includes formation of the protection glass 170 and the barrier dams 180. The barrier dam 180 encloses a compartment on the upper surface 111 of the semiconductor chip 110. The compartment may serve for different purposes such as accommodating micro lens module or other components that requires independent space. The compartment is then sealed by the protection glass 170. The first chip 120 is disposed on the protection glass 170. The chip package 100 integrates the semiconductor chip 110 and the first chip 120 to fulfill multiple functions and allows more combinations like micro lens module or other components that requires independent space. The application of the chip package is more flexible and broad. As shown in FIG. 5, a plurality of first connection portion 10 is formed and respectively, electrically connected to the first chip conductive pad 122 and the first connection portion 112. The first connection portion 130 may constitute solder ball portions 132, 136 and a solder wire portion 134. The solder ball portion 132 is soldered to the first chip conductive pad 122 of the first chip 120, while the solder ball portion 136 is soldered to the first conductive pad 112 of the semiconductor chip 110. The solder wire portion 134 connects the solder ball portions 132 and 136. As a result, a direct electrical connection is established between the first chip 120 and the semiconductor chip 110. However, the first connection portion 130 may be a metal clip or a conductive ribbon whose two ends directly yet respectively contact the first chip conductive pad 122 and the first conductive pad 112. The first connection portion 130 may be any other suitable couple means that forms direct electrical connection between the first chip conductive pad 122 and the first conductive pad 112.

Please refer to FIGS. 6 and 7. After the formation of the plurality of first connection portions 130 that is electrically connected to each first chip conductive pad 122 and each first conductive pad 112, a molding layer 140 covers the upper surface 111, the first chip 120 and the first connection portion 130. As shown in FIG. 6, the molding layer 140 packages the semiconductor chip 110, the first chip 120 and the first connection portion 130 as a whole. The molding layer 140 may be formed by covering the upper surface 111, the first chip 120 and the first connection portion 130 by molding materials. Materials of the molding may be epoxy molding compound or any other suitable molding materials for molding process. As shown in FIG. 7, the molding layer 140 undergoes lithography to form an opening 142 that exposes the second conductive pads 114. Subsequently, a metal redistribution layer 150 is formed in the opening 142 and electrically connected to the second conductive pad 114. The metal redistribution layer 150 extends to the molding layer 140. Finally, please refer back to FIG. 1. The packaging layer 160 covers the metal redistribution layer 150 and the molding layer 140, and the chip package 100 shown in FIG. 1 is complete.

In summary, the instant disclosure provides a chip package and method of manufacturing the same. The chip package integrates two or more chip in a stack, such that one single chip package has multiple functions and high efficiency. Between the chips, the electrical connection is achieved first within the chip package and then a metal redistribution layer serves as an external connection for the stack of two chips. In one package there will be two chips so as to exert more functionalities and higher efficiency, and at the same time the pattern design of the metal redistribution layer can be simplified. In other words, the metal redistribution layer does not need to electrically connect the semiconductor chip and the first chip directly. Accordingly, there is more flexibility in the pattern design of the metal redistribution layer, and the production cost can be greatly reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A chip package, comprising:
a semiconductor chip including at least an active area and at least a conductive pad disposed on an upper surface of the semiconductor chip;
at least a cavity recessing from a lower surface of the semiconductor toward the upper surface and exposing the conductive pad;
a molding layer covering the upper surface, a first chip and a first connection portion, the molding layer formed with an opening exposing a second conductive pad;
a metal redistribution layer disposed in the opening and electrically connected to the second conductive pad and extending to the molding layer; and
a packaging layer covering the metal redistribution layer and the molding layer.

2. The chip package of claim 1, further comprising:
a protection glass disposed between the semiconductor and the first chip; and
a barrier dam having a height and sandwiched between the protection glass and the semiconductor.

3. The chip package of claim 1, further comprising:
a second chip sandwiched between the semiconductor chip and the first chip, the second chip having at least a second chip conductive pad; and
a second connection portion electrically connecting the second conductive pad and the first conductive pad.

4. The chip package of claim 3, wherein an area of the second chip is larger than an area of the first chip.

5. The chip package of claim 3, wherein the second chip is a switch or an oscillator of an integrated passive device, a radio frequency circuit, an analogue device, a digital device, a mixed signal device or a micro-electro mechanical system.

6. The chip package of claim 3, wherein the second connection portion and the first connection portion respectively connect to different first conductive pads.

7. The chip package of claim 1, further comprising:
a second chip disposed on the upper surface and adjacent to the first chip, the second chip having at least a second chip conductive pad; and
a second connection portion electrically connecting the second chip conductive pad and the first conductive pad.

8. The chip package of claim 7, wherein the second chip is a switch or an oscillator of an integrated passive device, a radio frequency circuit, an analogue device, a digital device, a mixed signal device or a micro-electro mechanical system.

9. The chip package of claim 7, wherein the second connection portion and the first connection portion respectively connect to different first conductive pads.

10. The chip package of claim 1, further comprising a solder ball disposed on the packaging layer, the packaging layer formed with an opening exposing a portion of the metal redistribution layer, and the solder ball electrically connected to the metal redistribution layer through the opening of the packaging layer.

11. The chip package of claim 1, wherein the first chip is a switch or an oscillator of an integrated passive device, a radio frequency circuit, an analogue device, a digital device, a mixed signal device or a micro-electro mechanical system.

12. The chip package of claim 1, wherein an area of the semiconductor chip is larger than an area of the first chip.

13. The chip package of claim 1, further comprising an adhesive layer sandwiched between the upper surface of the semiconductor chip and the first chip.

14. The chip package of claim 13, wherein the adhesive layer includes a silver glue.

15. A method of manufacturing chip package, comprising:
providing a semiconductor wafer having a plurality of semiconductor chips arranged abreast, the semiconductor chip having at least a first conductive pad and at least a second conductive pad disposed on an upper surface of the semiconductor chip;
forming a plurality of first chips corresponding to the semiconductor chips, the first chips disposed on the upper surface, and each of the first chip having at least a conductive pad;
forming a plurality of first connection portions respectively electrically connected to each of the conductive pad of the first chips and each of the first conductive pad;
forming a molding layer covering the upper surface, the first chips and the first connection portions, the molding layer formed with an opening exposing the second conductive pad;
forming a metal redistribution layer in the opening and electrically connected to the second conductive pad, and the metal redistribution layer extending to the molding layer; and
forming a packaging layer covering the redistribution layer and the molding layer.

16. The method of claim 15, before the step of forming the first chips corresponding to the semiconductor chips further comprising:
forming a plurality of supporting elements corresponding to each of the semiconductor chips and disposed on the semiconductor chip; and
forming a plurality of protection glass on each of the supporting elements.

17. The method of claim 15, after the step of forming the first chips corresponding to the semiconductor chips further comprising:
forming a plurality of second chips respectively corresponding to the semiconductor chips, the second chips sandwiched between the semiconductor chip and the first chip, and the second chip having at least a conductive pad; and
forming a plurality of second connection portions respectively electrically connected to each of the conductive pads of the second chip and each of the first conductive pads.

18. The method of claim 17, wherein an area of the first chip is larger than an area of the second chip.

19. The method of claim 17, wherein the second chip is a switch or an oscillator of an integrated passive device, a radio frequency circuit, an analogue device, a digital device, a mixed signal device or a micro-electro mechanical system.

20. The method of claim 17, wherein the second connection portion and the first connection portion respectively connect to different first conductive pads.

21. The method of claim 15, after the step of forming the first chips corresponding to the semiconductor chips further comprising:
forming a plurality of second chips respectively corresponding to the semiconductor chips, the second chips disposed on the upper surface of the semiconductor chip and adjacent to the first chip, and the second chip having at least a conductive pad; and
forming a plurality of second connection portions respectively electrically connected to each of the conductive pads of the second chip and each of the first conductive pads.

22. The method of claim 21, the second chip is a switch or an oscillator of an integrated passive device, a radio frequency circuit, an analogue device, a digital device, a mixed signal device or a micro-electro mechanical system.

23. The method of claim 21, wherein the second connection portion and the first connection portion respectively connect to different first conductive pads.

24. The method of claim 15, further comprising forming a solder ball disposed on the packaging layer, the packaging layer formed with an opening exposing a portion of the metal redistribution layer, and the solder ball electrically connected to the metal redistribution layer through the opening of the packaging layer.

25. The method of claim 15, wherein the first chip is a switch or an oscillator of an integrated passive device, a radio frequency circuit, an analogue device, a digital device, a mixed signal device or a micro-electro mechanical system.

26. The method of claim 15, wherein an area of the semiconductor chip is larger than an area of the first chip.

27. The method of claim 15, further comprising forming an adhesive layer sandwiched between the upper layer of the semiconductor chip and the first chip.

28. The method of claim 27, wherein the adhesive layer includes a silver glue.

29. A chip package, comprising:
a semiconductor chip including at least an active area and at least a conductive pad disposed on an upper surface of the semiconductor chip;
at least a cavity recessing from a lower surface of the semiconductor toward the upper surface and exposing the conductive pad;
a molding layer covering the upper surface, a first chip and a first connection portion, the molding layer formed with an opening exposing a second conductive pad;
a redistribution layer disposed in the opening and electrically connected to the second conductive pad and extending to the molding layer; and
a packaging layer covering the redistribution layer and the molding layer.

30. The chip package of claim 29, further comprising:
a protection substrate disposed between the semiconductor and the first chip; and
a spacer having a height and sandwiched between the protection substrate and the semiconductor.

31. The chip package of claim 30, wherein the protection substrate is a protection glass, and the spacer is a barrier dam.

32. The chip package of claim 29, wherein the redistribution layer is made of metal.
